(19) United States
(12) Patent Application Publication
(10) Pub. No.: US 2017/0018714 A1
(43) Pub. Date: Jan. 19, 2017

(54) AN ELECTRODE AND MANUFACTURING METHOD THEREOF, AN ARRAY SUBSTRATE AND MANUFACTURING METHOD THEREOF

(71) Applicant: BOE TECHNOLOGY GROUP CO., LTD., Beijing (CN)

(72) Inventors: Dongfang Wang, Beijing (CN); Liangchen Yan, Beijing (CN); Ronggang Shangguan, Beijing (CN)

(21) Appl. No.: 14/907,896

(22) PCT Filed: Jul. 10, 2015
(86) PCT No.: PCT/CN15/83729

§ 371 Date: Jan. 27, 2016

(30) Foreign Application Priority Data
Mar. 3, 2015 (CV) 201510094993.8

(51) Int. Cl. H01L 51/00; H01L 27/32; H01L 51/56; H01L 51/52

(52) U.S. Cl. CPC H01L 51/0023; H01L 51/5203; H01L 51/5275; H01L 27/3262; H01L 51/56

(57) ABSTRACT

The present invention provides an electrode and manufacturing method thereof, and an array substrate and manufacturing method thereof. The manufacturing method of the electrode comprises: forming a ZnON material layer on a metal electrode layer; etching the formed ZnON material layer to form a microlens structure layer; forming a transparent electrode layer on the microlens structure layer. In the present invention, due to use of the ZnON material as the material for forming the microlens structure layer, an alkaline or weakly acidic solution can be used at the time of forming microlens structures by etching, which can thereby prevent the metal electrode layer from erosion.

### RELATED APPLICATIONS

The present application is the U.S. national phase entry of PCT/CN2015/083729 with an International filing date of Jul. 10, 2015, which claims the benefit of Chinese Application No. 201510094993.8, filed Mar. 3, 2015, the entire disclosures of which are incorporated herein by reference.

### FIELD

The present invention relates to the display technical field, particularly to an electrode and manufacturing method thereof, and an array substrate and manufacturing method thereof.

### BACKGROUND

In an organic light-emitting diode (OLED) display panel, in order to improve the work function and reflectivity of the bottom electrode, an electrode as shown in FIG. 1 would may be adopted as the bottom electrode. As shown in FIG. 1, the electrode comprises a metal electrode layer 10, a microlens structure layer 11 formed on the bottom electrode, and a transparent electrode layer 12 (which is usually made of indium tin oxide (ITO) material) formed on the microlens structure layer. The metal electrode layer 10 is generally an electrode layer with reflective function. Light is reflected by the metal electrode layer 10 after irradiating the metal electrode layer. When the reflected light passes through respective microlenses in the microlens structure layer 11, for reasons such as the diffusing reflection effect of microlens, the effect of microlens and lowered refraction index caused by nanoparticles, light that penetrates through the transparent electrode layer 12 is significantly increased compared to that when no microlens structure layer is arranged.

In the prior art, the microlens structure layer 2 is generally manufactured by the following process: forming an indium tin oxide ITO material layer on the metal electrode layer 10, and then etching the ITO material layer using a solution to form a microlens structure layer 11 comprising a plurality of microlens structures. In order to etch the ITO material layer, it is generally required to use a strongly acidic solution, but a solution of too strong acidity may cause the metal electrode layer 10 below the ITO material layer to be etched, thus influencing conductive and reflective properties of the metal electrode layer 10.

### SUMMARY

It is an object of the present invention to provide a method capable of preventing a metal electrode layer in an electrode from being etched.

The present invention provides an electrode comprising a metal electrode layer, a microlens structure layer formed on the metal electrode layer, and a transparent electrode layer formed on the microlens structure layer, wherein the microlens structure layer is made of zinc oxynitride (ZnON) material.

Further, a microlens structure in the microlens structure layer has a height of 50 nm to 500 nm.

Further, the transparent electrode layer is made of indium tin oxide (ITO) material, indium zinc oxide (IZO) material, indium tin zinc oxide (InSnZnO) ITZO material or indium gallium zinc oxide (IGZO) material.

The present invention further discloses an array substrate comprising: a substrate, a transistor array formed on the substrate, and an electroluminescent element array formed on the transistor array, wherein a bottom electrode in the electroluminescent element array is the aforesaid electrode.

The present invention further provides a method for manufacturing an electrode, comprising the steps of:

forming a ZnON material layer on a metal electrode layer;

etching the formed ZnON material layer to form a microlens structure layer; and

forming a transparent electrode layer on the microlens structure layer.

In some implementations, the ZnON material layer formed on the metal electrode layer has a thickness of 50 nm to 500 nm.

In some implementations, said etching the formed ZnON material layer to form a microlens structure layer comprises:

etching the ZnON material layer using an alkaline solution to form a microlens structure layer.

In some implementations, said etching the formed ZnON material layer to form a microlens structure layer comprises:

etching the ZnON material layer using a hydrochloric acid, acetic acid or oxalic acid solution with a mass ratio of 0.1% to 5% to form a microlens structure layer.

In some implementations, said forming a ZnON material layer on a metal electrode layer comprises:

depositing ZnON material on the metal electrode layer; and

annealing the deposited ZnON material at a temperature of 200° C. to 500° C. to obtain a ZnON material layer.

In some implementations, said depositing ZnON material on the metal electrode layer comprises:

depositing ZnON material on the metal electrode layer by sputtering process.

In some implementations, the transparent electrode layer is made of ITO material, IZO material, ITZO material or IGZO material.

The present invention further provides a method for manufacturing an array substrate, characterized in comprising:

forming a transistor array on a substrate and forming an electroluminescent element array on the transistor array, wherein, at the time of forming an electroluminescent element array on the transistor array, a bottom electrode of the electroluminescent element array is manufactured using the aforesaid method.

In the present invention, due to use of ZnON as the material for forming the microlens structure layer, an alkaline solution or weakly acidic solution can be used at the time of forming the microlens structures by etching, which can thereby alleviate or even avoid erosion of the metal electrode layer.

### BRIEF DESCRIPTION OF DRAWINGS

FIG. 1 is a schematic diagram of the structure of an electrode in the prior art;

FIG. 2 is a flow schematic diagram of a method for manufacturing an electrode as provided by an embodiment of the present invention;

FIG. 3 is a schematic diagram of the structure of an electrode as provided by an embodiment of the present invention;

FIG. 4 is a schematic diagram of the structure of an array substrate as provided by an embodiment of the present invention.

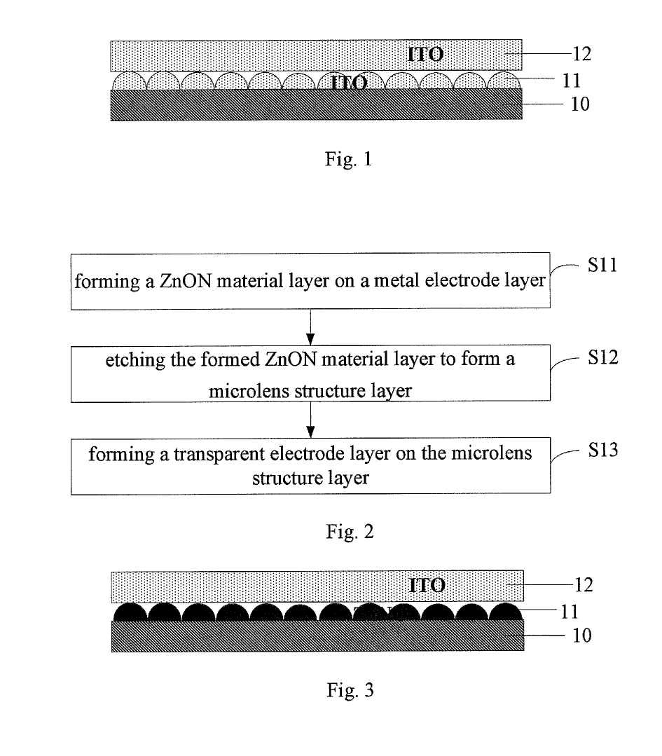

### DETAILED DESCRIPTION

To improve the clarity of the disclosure of the present invention described herein, technical solutions of the embodiments of the present invention will be described as follows in combination with the drawings accompanying this disclosure. As is apparent, the described embodiments are only a part of the embodiments of the present invention rather than all embodiments. Other embodiments obtained by those ordinarily skilled in the art on the basis of the present disclosure, without spending inventive efforts or undue experimentation, fall within the protection scope of the present invention.

An embodiment of the present invention provides a method for manufacturing an electrode. As shown in FIG. 2, the method may comprise the following procedure:

step S11, forming a ZnON material layer on a metal electrode layer;

step S12, etching the formed ZnON material layer to form a microlens structure layer; and

step S13, forming a transparent electrode layer on the microlens structure layer.

In some embodiments, ZnON is used as the material for forming the microlens structure layer. Since ZnON can be etched by an alkaline or weakly acidic solution, in the technical solutions provided by the present invention, the alkaline or weakly acidic solution can be used in the course of forming microlens structures by etching, which can thereby alleviate or even avoid erosion of the metal electrode layer.

Prior to step S11, the aforesaid method may further comprise step S01 (not shown in the drawings) of forming a metal electrode layer. Specifically, the metal electrode layer can be formed using a metal material with relatively high reflectivity and relatively low resistivity. For instance, AlNd or AlNiB may be used to form the metal electrode layer. Further, upon implementation, a corresponding metal material can be deposited on the substrate of the electrode using sputtering process. When this electrode is utilized as a bottom electrode of an OLED display device, the substrate may include a transparent substrate provided with a transistor array for controlling luminescence of the OLED.

Upon implementation, in step S11, the ZnON material layer formed on the metal electrode layer may have a thickness of 50 nm to 500 nm. Such thickness enables a reflective electrode to have better reflectivity.

Upon implementation, step S11 may specifically comprise: depositing ZnON material on the metal electrode layer; annealing the deposited ZnON material at a temperature of 200° C. to 500° C. to obtain a ZnON material layer. In the course of carrying out the present invention, inventor of the present application found that the ZnON material layer obtained by annealing the ZnON material was easier to etch and could make the microlenses formed in subsequent processes more homogeneous and have better morphology, which could further improve transmittance of the light reflected by the metal electrode layer in the transparent electrode layer.

Upon implementation, ZnON material can be deposited on the metal electrode layer by sputtering process. Certainly, the process to be specifically used would not influence the implementation of the present invention as long as the ZnON material can be deposited on the metal electrode layer. The corresponding technical solution should also fall within the protection scope of the present invention.

Upon implementation, in step S12 an alkaline solution can be used to etch the ZnON material to form a microlens structure layer. The alkaline solution here generally indicates a strongly alkaline solution. Specifically speaking, it can be Ca(OH)₂ solution, KOH solution, NaOH solution, and the like. These solutions would not erode the metal electrode layer below the ZnON material layer and can well protect the metal electrode layer from damage. Upon implementation, the alkaline solution here may specifically be Ca(OH)₂ solution, KOH solution or NaOH solution with a mass ratio of 0.1% to 0.5%.

In addition, in practical applications, a weakly acidic solution may also be used to etch the ZnON material layer to form a microlens structure. Specifically speaking, a hydrochloric acid, acetic acid or oxalic acid solution with a mass ratio of 0.1% to 0.5% can be used to etch the ZnON material layer to form a microlens structure layer. These acidic solutions have a relatively high pH value, and the rate of reaction with the metal electrode layer is relatively slow, which can decrease the degree of erosion of the metal electrode layer.

Upon implementation, in step S13, ITO material, IZO material, ITZO material or IGZO material can be used to make the transparent electrode layer.

The present invention further provides a method for manufacturing an array substrate. The method may comprise steps of forming a transistor array on a substrate and forming an electroluminescent element array on the transistor array, wherein, at the time of forming an electroluminescent element array on the transistor array, a bottom electrode of the electroluminescent element array can be manufactured using the aforesaid method.

Specifically, the step of forming a transistor array on a substrate may comprise: providing a transparent substrate and cleaning the transparent substrate using a standard method; then depositing 50 nm to 400 nm Mo as a gate material layer using sputtering process or evaporation process, then performing patterning to form a gate electrode pattern; then preparing a SiOx (x is a positive integer) gate insulating layer with a thickness of 100 nm to 500 nm on the gate pattern using chemical vapor deposition process; depositing IGZO with a thickness of 10 nm to 80 nm on the SiOx gate insulating layer using sputtering process, and performing lithography and etching as needed to form an active layer pattern; depositing SiOx with a thickness of 200 nm on the active layer pattern using chemical vapor deposition process or sputtering process, depositing SiNy or SiOmNn (y, m, n are all positive integers) with a thickness of 100 nm as an etching barrier layer on the SiOx, performing patterning as needed; preparing Mo with a thickness of 50 nm to 400 nm as a source drain electrode film on the etching barrier layer using sputtering process, and performing lithography and etching based on the desired pattern to form a source and drain pattern; then depositing SiOx or SiOxNy with a thickness of 100 nm to 500 nm as a passivation layer on the source and drain pattern using chemical vapor deposition process or sputtering process, performing patterning as needed; then spin-coating a resin layer and patterning it to form a flat surface that facilitates the formation of a metal electrode layer and prevent vapor in air from entering the transistor array.

After the transistor array has been formed, the step of forming an electroluminescent element array may specifically comprise:

forming a metal electrode layer on the resin layer;

forming a ZnON material layer on the metal electrode layer;

etching the formed ZnON material layer to form a microlens structure layer;

forming a transparent electrode layer on the microlens structure layer.

Upon implementation, vias can also be formed in the aforesaid resin layer. The metal electrode layer is connected with the source and drain pattern in the transistor array through the vias. At that time, the formed metal electrode layer, microlens structure layer and transparent electrode layer act as an anode of the organic electroluminescent element.

In practical applications, it may be the case that only a part of the organic electroluminescent element array is formed on the array substrate, without formation of an organic emission layer and a top electrode. In specific applications, it is possible to form an organic emission layer after forming a top electrode pattern on another transparent substrate, and seal the above formed array substrate using the another transparent substrate and the structures formed thereon as a cover plate, thereby forming a complete organic electroluminescent element array. When the method provided by the present invention is used for manufacturing such array substrate, it does not comprise the steps of forming an organic emission layer and a top electrode.

At that time, the manufacturing method provided by the present invention may not comprise the steps of forming an organic emission layer and a top electrode.

In another aspect, the present invention further provides an electrode. As shown in FIG. 3, the electrode may comprise: a metal electrode layer 10, a microlens structure layer 11 formed on the metal electrode layer, and a transparent electrode layer 12 formed on the microlens structure layer; wherein, the microlens structure layer 11 is made of ZnON material.

Since the microlens structure layer in the electrode provided by the present invention is made of ZnON material, an alkaline solution or weakly acidic solution can be used to etch the ZnON material layer to form the microlens structure layer, which can alleviate or avoid etching of the metal electrode layer in the electrode.

Upon implementation, the height of the microlens structure in the microlens structure layer 11 here may specifically be 50 nm to 500 nm. Such height enables a reflecting electrode to have better reflectivity.

Upon implementation, the transparent electrode layer 12 may be made of ITO material, IZO material, ITZO material or IGZO material.

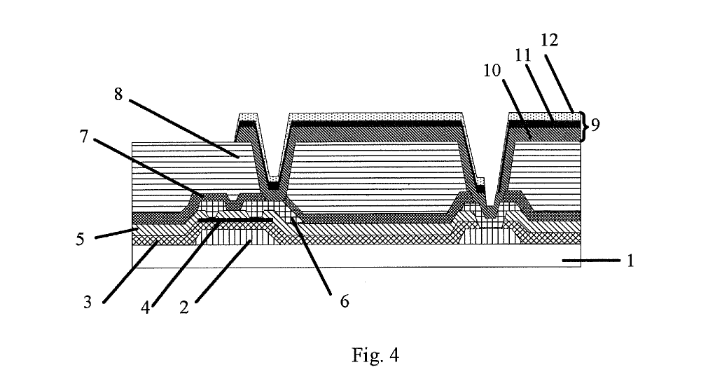

In another aspect, the present invention further provides an array substrate. As shown in FIG. 4, the array substrate may comprise a transparent substrate 1, a transistor array, and an organic electroluminescent element array formed on the transparent substrate 1, wherein the transistor array comprises: a gate pattern 2 formed on the base substrate 1, a gate insulating layer 3 formed above the gate pattern 2, an active layer pattern 4 formed above the gate insulating layer 3, an etching barrier layer 5 formed on the active layer pattern 4 and the gate insulating layer 3, a source and drain pattern 6 formed above the etching barrier layer 5, a passivation layer 7 formed on the source and drain pattern 6, and a resin layer 8 formed on the passivation layer 7. The organic electroluminescent element array comprises a bottom electrode 9 formed on the resin layer 8, the bottom electrode 9 comprising a metal electrode layer 10, a microlens structure layer 11 formed on the bottom electrode, and a transparent electrode layer 12 formed on the microlens structure layer.

In practical applications, the aforesaid array substrate may be a WOLED (White OLED)+COA (Color On Array) substrate, or may also be a PLED (polymer light-emitting diode) array substrate, and the like.

The present disclosure includes specific embodiments of the present invention. However, the protection scope of the present invention is not limited to the embodiments and/or implementations described herein. Any variation or substitution that can be easily conceived by persons having skill in the technical field of the present invention shall be covered within the protection scope of the present invention. Therefore, the protection scope of the present invention shall be based on the protection scope of the claims.

1-12. (canceled)

13. An electrode, characterized in that, comprising:
a metal electrode layer;
a microlens structure layer having a plurality of microlens structures and formed on said metal electrode layer; and a
transparent electrode layer formed on said microlens structure layer;
wherein said microlens structure layer is made of zinc oxynitride material.

14. The electrode according to claim 13, wherein the microlens structures in said microlens structure layer have a height of 50 nm to 500 nm.

15. The electrode according to claim 13, wherein said transparent electrode layer is made of indium tin oxide material, indium zinc oxide material, indium tin zinc oxide material or indium gallium zinc oxide material.

16. An array substrate, comprising:
a substrate;
a transistor array formed on said substrate; and
an electroluminescent element array formed on said transistor array;
wherein, a bottom electrode in said electroluminescent element array comprises:
a metal electrode layer;
a microlens structure layer having a plurality of microlens structures and formed on said metal electrode layer, and a transparent electrode layer formed on said microlens structure layer;
wherein said microlens structure layer is made of zinc oxynitride material.

17. The array substrate according to claim 16, wherein the microlens structures in said microlens structure layer have a height of 50 nm to 500 nm.

18. The array substrate according to claim 16, wherein said transparent electrode layer is made of indium tin oxide material, indium zinc oxide material, indium tin zinc oxide material or indium gallium zinc oxide material.

19. A method for manufacturing an electrode, comprising:
forming a zinc oxynitride material layer on a metal electrode layer;
etching the formed zinc oxynitride material layer to form a microlens structure layer; and
forming a transparent electrode layer on said microlens structure layer.

20. The method according to claim 19, wherein the zinc oxynitride material layer formed on said metal electrode layer has a thickness of 50 nm to 500 nm.

21. The method according to claim 19, wherein etching the formed zinc oxynitride material layer to form a microlens structure layer comprises:
etching the zinc oxynitride material layer using an alkaline solution to form a microlens structure layer.

22. The method according to claim 19, wherein etching the formed zinc oxynitride material layer to form a microlens structure layer comprises:
etching the zinc oxynitride material layer using a hydrochloric acid, acetic acid or oxalic acid solution with a mass ratio of 0.1% to 5% to form a microlens structure layer.

23. The method according to claim 19, wherein forming a zinc oxynitride material layer on a metal electrode layer comprises:
depositing zinc oxynitride material on said metal electrode layer; and
annealing the deposited zinc oxynitride material at a temperature of 200° C. to 500° C. to obtain a zinc oxynitride material layer.

24. The method according to claim 23, wherein depositing zinc oxynitride material on a metal electrode layer comprises:
depositing zinc oxynitride material on said metal electrode layer by sputtering process.

25. The method according to claim 19, wherein said transparent electrode layer is made of indium tin oxide material, indium zinc oxide material, indium tin zinc oxide material or indium gallium zinc oxide material.

26. A method for manufacturing an array substrate, comprising:
forming a transistor array on a substrate; and
forming an electroluminescent element array on said transistor array;
wherein, at the time of forming an electroluminescent element array on said transistor array, a bottom electrode of said electroluminescent element array is manufactured using a method comprising:
forming a zinc oxynitride material layer on a metal electrode layer;
etching the formed zinc oxynitride material layer to form a microlens structure layer; and
forming a transparent electrode layer on said microlens structure layer.

27. The method according to claim 26, wherein the zinc oxynitride material layer formed on said metal electrode layer has a thickness of 50 nm to 500 nm.

28. The method according to claim 26, wherein etching the formed zinc oxynitride material layer to form a microlens structure layer comprises:
etching the zinc oxynitride material layer using an alkaline solution to form a microlens structure layer.

29. The method according to claim 26, wherein etching the formed zinc oxynitride material layer to form a microlens structure layer comprises:
etching the zinc oxynitride material layer using a hydrochloric acid, acetic acid or oxalic acid solution with a mass ratio of 0.1% to 5% to form a microlens structure layer.

30. The method according to claim 26, wherein forming a zinc oxynitride material layer on a metal electrode layer comprises:
depositing zinc oxynitride material on said metal electrode layer; and
annealing the deposited zinc oxynitride material at a temperature of 200° C. to 500° C. to obtain a zinc oxynitride material layer.

31. The method according to claim 30, wherein depositing zinc oxynitride material on a metal electrode layer comprises:
depositing zinc oxynitride material on said metal electrode layer by sputtering process.

32. The method according to claim 26, wherein said transparent electrode layer is made of indium tin oxide material, indium zinc oxide material, indium tin zinc oxide material or indium gallium zinc oxide material.
